(19) United States
(12) Patent Application Publication
(10) Pub. No.: US 2025/0336879 A1
(43) Pub. Date: Oct. 30, 2025

(54) MULTIPLE INTEGRATED CIRCUIT CHIP/MODULE EMBEDDING BY UNDERFILLING AND DIRECT PRINT ADDITIVE MANUFACTURING

(71) Applicant: University of South Florida, Tampa, FL (US)

(72) Inventors: Ruoke Liu, Tampa, FL (US); Jing Wang, Tampa, FL (US)

(21) Appl. No.: 19/189,377

(22) Filed: Apr. 25, 2025

Related U.S. Application Data
(60) Provisional application No. 63/638,448, filed on Apr. 25, 2024.

(51) Int. Cl. H01L 23/00; H01L 21/48; H01L 23/13; H01L 23/31

(52) U.S. Cl. CPC H01L 24/48; H01L 21/4803; H01L 23/13; H01L 23/3121; H01L 24/32; H01L 24/45; H01L 24/73; H01L 24/83; H01L 24/85; H01L 24/29; H01L 2224/29023; H01L 2224/2919; H01L 2224/32225; H01L 2224/4519; H01L 2224/48225; H01L 2224/73215; H01L 2224/73265; H01L 2224/83085; H01L 2224/85855; H01L 2924/1815

(57) ABSTRACT

Methods and techniques are provided for using a conductive epoxy to create interconnects across a gap between an embedded integrated circuit chip and a dielectric substrate. The chosen epoxy is adhesive and thixotropic so that it sticks well and won't lose its volume after a drying process. Further, a liquid dielectric ink is used as an underfill material to not only cover and protect the interconnects but also act as a dielectric layer. This allows as for additional dielectric layers with corresponding interconnects and vias to form a multilayer structure with additional embedded chips. The disclosed methods and techniques can be implemented using direct print additive manufacturing processes.

### CROSS-REFERENCE TO RELATED APPLICATIONS

This application claims priority to and benefit of U.S. Provisional Application Ser. No. 63/638,448 filed on Apr. 25, 2024. The disclosure of which is hereby incorporated by reference in its entirety.

### BACKGROUND

Traditional methods for embedding chips in dialetric substrates involve milling a cavity into the substrate and placing the chip into the milled cavity. However, this process always results in a gap between the chip and the substrate. Accordingly, to connect the pads of the chip to the rest of the connectors on the substrate, the interconnects from the pads to the substrate must traverse the gap.

Current solutions for traversing the gap include using conductive ink to “draw” the interconnects from the pads across the gap and onto the substrate. Another solution involves filling the gap with a dielectric material and then printing the interconnect using silver paste or another material. However, there are drawbacks associated with both solutions. With respect to conductive ink, the ink can easily flow into the gap which may result in short circuiting and can lead to vulnerability when printing a subsequent dielectric layer with regular filament on top of the printed interconnects.

With respect to the gap filling method, there are limited choices for selecting an appropriate material for gap filling. Furthermore, when filling the gap, the manufacturing process must be paused while the gap is filled and planarized.

### SUMMARY

Methods and techniques are provided for using a conductive epoxy to create interconnects across a gap between an embedded integrated circuit chip and a dielectric substrate. The chosen epoxy is adhesive and thixotropic so that it sticks well and won't lose its volume after a drying process. Further, a liquid dielectric ink is used as an underfill material to not only fully refill the gap underneath and surrounding the embedded integrated circuit chip from its surrounding substrate and cover and protect the interconnects but also act as a dielectric layer on top of the printed interconnects to encapsulate them. This allows as for additional dielectric layers with corresponding interconnects and vias to form a multilayer structure with additional embedded chips. The disclosed methods and techniques can be implemented using direct print additive manufacturing processes.

In some aspects, the techniques described herein relate to a method for chip embedding including: placing an integrated circuit chip into a dielectric substrate, wherein the integrated circuit chip includes a plurality of pads; connecting each of the plurality of pads to the dielectric substrate using conductive epoxy to form interconnects from each pad of the plurality of pads on to the dielectric substrate; and covering the interconnects and the dielectric substrate with a dielectric liquid to form a dielectric layer on top of the dielectric substrate and the interconnects.

In some aspects, the techniques described herein relate to a method, wherein the dielectric liquid includes a dielectric ink.

In some aspects, the techniques described herein relate to a method, wherein the dielectric ink hardens to form the dielectric layer.

In some aspects, the techniques described herein relate to a method, wherein the conductive epoxy is adhesive and thixotropic.

In some aspects, the techniques described herein relate to a method, wherein the conductive epoxy includes EPO-TEK EK1000.

In some aspects, the techniques described herein relate to a method, further including curing the conductive epoxy prior to covering the interconnects.

In some aspects, the techniques described herein relate to a method, further including: covering a top of the integrated circuit chip with the conductive epoxy.

In some aspects, the techniques described herein relate to a method, further including covering the interconnects with the dielectric liquid without covering the conductive epoxy on top of the integrated circuit chip.

In some aspects, the techniques described herein relate to a method, further including creating a via opening to the integrated circuit chip which can be refilled using the conductive epoxy to form a vertical interconnect.

In some aspects, the techniques described herein relate to a method, wherein the integrated circuit chip includes a QFN chip, a chip under any packaging form, or an unpackaged chip in its intrinsic die format.

In some aspects, the techniques described herein relate to a method, further including milling a cavity into the dielectric substrate and placing the integrated circuit chip into the cavity.

In some aspects, the techniques described herein relate to a method, wherein there is a gap formed between the integrated circuit chip and the cavity when the integrated circuit chip is placed in the cavity and further including filling the gap (both underneath and surrounding the integrated circuit chip) with the dielectric liquid.

In some aspects, the techniques described herein relate to a method, wherein the interconnects extend over the gap.

In some aspects, the techniques described herein relate to a method, wherein the connecting and covering steps are performed as part of a direct print additive manufacturing process.

In some aspects, the techniques described herein relate to a computer-readable medium with computer-executable instructions stored thereon that when executed by a computing device cause the computing device to: place an integrated circuit chip into a dielectric substrate, wherein the integrated circuit chip includes a plurality of pads; connect each of the plurality of pads to the dielectric substrate using conductive epoxy to form interconnects from each pad of the plurality of pads on to the dielectric substrate; and cover the interconnects and the dielectric substrate with a dielectric liquid to form a dielectric layer on top of the dielectric substrate and the interconnects.

In some aspects, the techniques described herein relate to a computer-readable medium, further including milling a cavity into the dielectric substrate and placing the integrated circuit chip into the cavity.

In some aspects, the techniques described herein relate to a computer-readable medium, wherein there is a gap formed between the integrated circuit chip and the cavity when the integrated circuit chip is placed in the cavity and further including filling the gap with the dielectric liquid.

In some aspects, the techniques described herein relate to a computer-readable medium, wherein the interconnects extend over the gap.

In some aspects, the techniques described herein relate to a computer-readable medium, wherein the computing device is part of an advanced additive manufacturing platform or a robotic and automated manufacturing system (or an advanced additive manufacturing platform in the form of a fully automated manufacturing tool, which is also known as a direct print additive manufacturing system).

In some aspects, the techniques described herein relate to a device including: a dielectric substrate including a cavity; an integrated circuit chip placed into the cavity and including a plurality of pads, wherein each of the plurality of pads is connected to the dielectric substrate using conductive epoxy to form interconnects from each of the plurality of pads on the dielectric substrate; and a layer of dielectric liquid covering the interconnects and the dielectric substrate and filling a gap between the integrated circuit chip and the dielectric substrate, and wherein the dielectric liquid forms a dielectric layer on top of the dielectric substrate and the interconnects.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The foregoing summary, as well as the following detailed description of illustrative embodiments, is better understood when read in conjunction with the appended drawings. For the purpose of illustrating the disclosed embodiments, there is shown in the drawings example constructions of the embodiments; however, the possible embodiments are not limited to the specific methods and instrumentalities disclosed. In the drawings:

FIGS. 1A and 1B are illustrations of different views of an example integrated circuit chip and dielectric substrate;

FIGS. 2A and 2B are illustrations of different views of an example integrated circuit chip and dielectric substrate with applied epoxy interconnects;

FIG. 3 is an illustration of an example integrated circuit chip and dielectric substrate with applied epoxy interconnects and dielectric ink;

FIG. 4 is an illustration of an example method for applying epoxy interconnects and dielectric ink to an integrated circuit chip in a dielectric substrate; and

FIG. 5 is a schematic diagram of computer hardware that may be utilized to implement aspects of the disclosed systems and methods.

### DETAILED DESCRIPTION

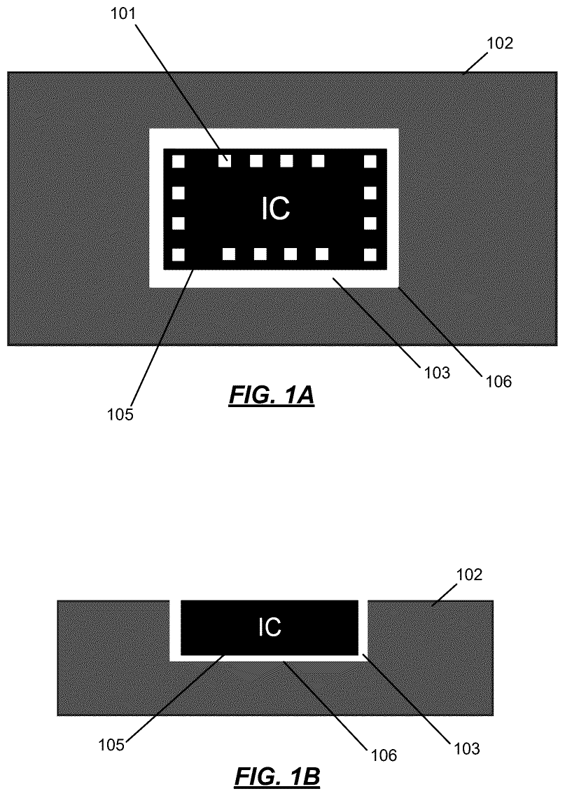

FIGS. 1A and 1B are illustrations of different views of an example integrated circuit chip 105 and dielectric substrate 102. The integrated circuit chip (“IC”) 105 may be a quad-flat no-leads (“QFN”) chip, however other types of chips (both packaged chips in a form other than QFN format and unpackaged dies) may be supported. The IC 105 may include a plurality of pads 101 (shown as a series of white squares) through which one or more electrical connects with the IC 105 may be made. Note that the number of pads 101 is for illustration only, and more or fewer pads 101 may be supported.

As shown, the IC 105 may be placed within a cavity 106 of a dielectric substrate 102. The dielectric substrate 102 may be made of a variety of dielectric materials including, but not limited to, silicon dioxide and silicon nitride. Other materials may be used.

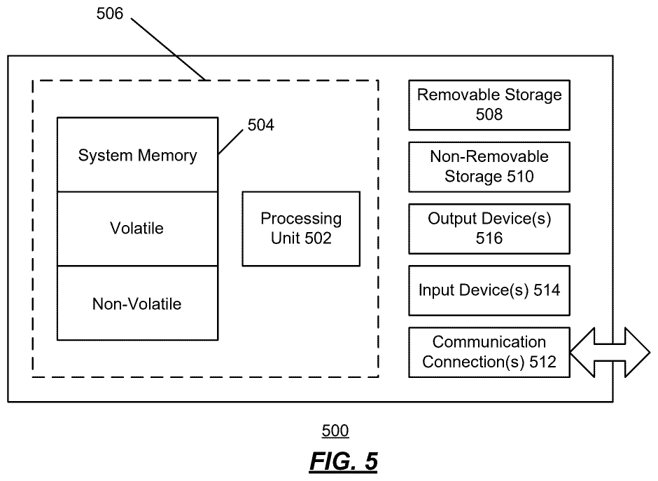

The cavity 106 may be sized to receive the IC 105 and may have been milled using one or more milling tools or an additive manufacturing platform controlled by a computing device such as the computing device 500 illustrated with respect to FIG. 5.

As can be seen in FIGS. 1A and 1B, when the IC 105 is placed in the cavity 106 of the dielectric substrate 102 there is a gap 103 formed between the walls of the substrate 102 and the IC 105 because the IC 105 is slightly smaller than the cavity 106. The technique described herein can accommodate a very wide gap range of a few micrometers to a few hundreds of micrometers to allow high yield refill of the gap between embedded IC chip and its surrounding substrate. However, any size gap 103 may be supported. As described above, the gap 103 results in difficulties and inefficiencies in connecting the pads 101 with other electrical components that may be part of the dielectric substrate 102 such as vias and other electrical connectors.

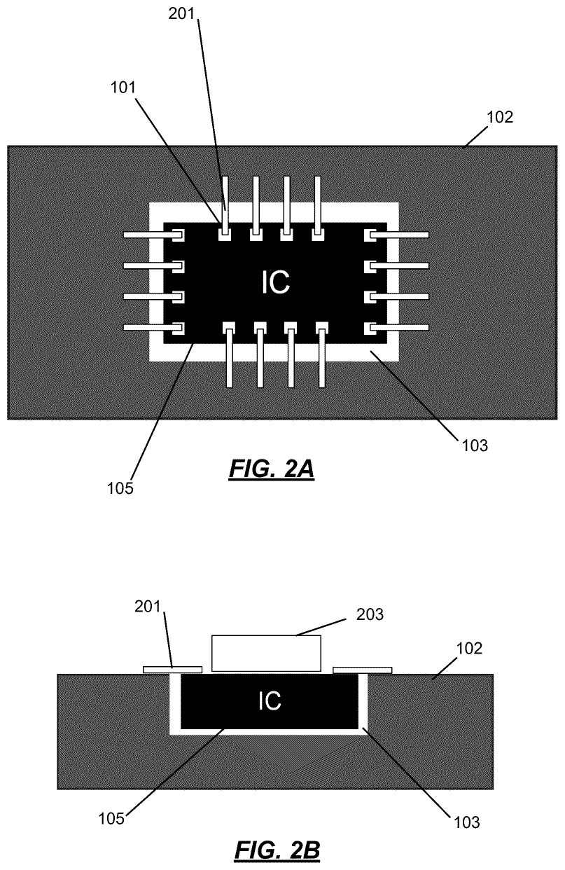

Continuing to FIGS. 2A and 2B, to bridge the gap 103 and to solve the problems noted above, one or more interconnects 201 may be added that connect each pad 101 of the IC 105 to the dielectric substrate 102. The interconnects 210 may be used to connect the pads 101 to other electrical connections or components that may be added to the dielectric substrate 102. The interconnects 210 may be added using a process controlled by a computing device such as the computing device 500.

In some embodiments, the interconnects 201 may be made from conductive epoxy. Other materials may be used for the interconnects 201. The conductive epoxy may be adhesive and thixotropic such that after it is applied to the IC 105 and the dielectric substrate 102 so that it maintains its volume and does not migrate or fall into the gap 103 after application. This may prevent the epoxy from pulling away from the pads 101 after it dries, and from moving or falling into the gap 103 and causing short-circuits. A suitable epoxy includes EPO-TEK® EK1000. Other epoxies may be used.

As shown in FIG. 2B at 203, additional conductive epoxy 203 (or other conductive material) may further be added to the top of the IC 105. As will be discussed further below, the additional conductive epoxy may be used to connect a conductive component to the top of the IC 105 after an additional dielectric layer has been added. The conductive component may be a heat sink or a thermal management feature to create a low-thermal resistance heat dissipation. Also contemplated (but not shown) is that one or more vertical interconnects 201 may be added to one or more of the pads 101 to create vias between the IC 105 and the additional dielectric layers.

After the interconnects 201 have been added to the IC 105 and the dielectric substrate 102, the epoxy may be put through a curing process. The curing process may depend on the type of epoxy used but may include curing the epoxy at an elevated temperature for a period of time. For an epoxy such as EPO-TEK® EK1000, the epoxy can be cured at temperatures ranging from 125° C. to 200° C. with durations varying from 15 mins to 2.5 hours.

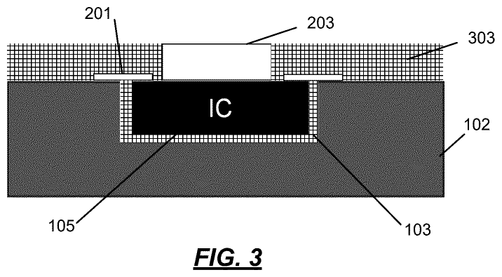

Continuing to FIG. 3, after the conductive epoxy has cured, a layer of dielectric ink 303 may be applied on top of the dielectric substrate and the interconnects 201. Suitable dielectric inks may include a variety of suitable inks. For high permittivity dielectrics, Creative Material 128-49 dielectric may be used. As another example, EPO-TEK® 302-3M may be used. EPO-TEK® 302-3M has desirable properties such as a relative low dielectric loss tangent of 0.006 and mild curing temperature conditions (65° C. for 3 hours). The dielectric ink 303 fills the gaps 103 and secures the interconnects 201 to the pads 101 and the substrate 102.

As shown, the dielectric ink 303 is deposited at thickness that is sufficient to cover the interconnects 201 while also allowing the conductive component 203 (and any vertical interconnects or vias) to be exposed. The dielectric ink 303 may be added using a process controlled by a computing device such as the computing device 500.

As may be appreciated, the process used to embed the IC 105 into the substrate, connect the pads 101 using conductive epoxy interconnects 201, and create a new dielectric layer using dielectric ink 303 may be performed using a direct print additive manufacturing process. The process may be repeated on top of subsequent dielectric layers of ink 303 to allow for the creation of complicated packages comprised of multiple ICs 105, with both vertical and horizonal epoxy interconnects 201, held together by layers of dielectric ink 303.

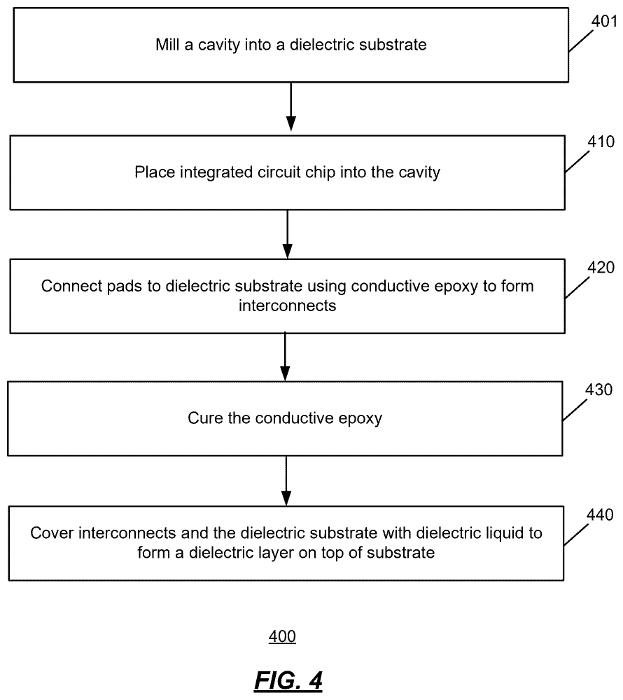

FIG. 4 is an illustration of an example method 400 for applying epoxy interconnects and dielectric ink to an integrated circuit chip in a dielectric substrate. The method 400 may be implemented by one or more computing devices 500 including a standalone additive manufacturing platform.

At 401, a cavity is milled or laser machined into a dielectric substrate. Such a cavity can be formed by directly 3D printing the dielectric substrate while having the cavity left within the 3D printed substrate as an open cavity. The cavity 106 may be milled or laser micro-machined under the control of the computing device 500 and the additive manufacturing platform as part of a direct print additive manufacturing process.

At 410, an integrated circuit is placed into the cavity. The IC 105 may be placed into the cavity 106 under the control of the computing device 500 and the additive manufacturing platform. The standalone additive manufacturing platform may include an integrated pick-and-place head and a pico-second or femto-second laser for micromachining. With its current wavelength set at 356 nm, the integrated pico-second pulsed laser machining can achieve a minimal laser trimmed size of 3 micrometers. The IC 105 may include a plurality of pads 101. When placed in the cavity 106, there may be a gap 103 formed between the IC 105 and one or more walls of the cavity 106.

At 420, pads are connected to the dielectric substrate using conductive epoxy to form interconnects. The pads may be connected under the control of the computing device 500 and the additive manufacturing platform. The standalone additive manufacturing platform may include an integrated pick-and-place head, pico-second or femto-second laser for micromachining, fused deposition modeling (for 3D printing of a dielectric from any chosen thermoplastic) and micro-dispensing that can print both conductive traces by using any conductive inks, pastes or epoxies (e.g., EPO-TEK EK1000) or print a dielectric layer by using a chose liquid dielectric (e.g., EPO-TEK 302-3M).

The interconnects 201 may be connected to each pad 101 and may span or traverse the gap 103 horizontally to connect to the substrate 102. In some embodiments, the interconnects 201 may include vertical interconnects 201 (i.e., vias) that are meant to connect one or more of the pads 101 to a subsequently deposited dielectric layer.

At 430, the conductive epoxy is cured. The epoxy of the interconnects 201 may be cured under the control of the computing device 500 and the additive manufacturing platform.

At 440, the interconnects and the substrate are covered with a dielectric liquid to form a dielectric layer on top of the substrate. The dielectric ink 303 may be deposited under the control of the computing device 500 and the additive manufacturing platform. The dielectric ink 303 may completely fill the gap 103 and may secure the interconnects 201. After drying, the dielectric ink 303 may form a new dielectric layer on top of the dielectric substrate 102. The method 400 may then be repeated where additional ICs 105 and interconnects may be placed on subsequent layers of dielectric ink as part of a continuing direct print additive manufacturing process.

FIG. 5 shows an exemplary computing environment in which example embodiments and aspects may be implemented. The computing device environment is only one example of a suitable computing environment and is not intended to suggest any limitation as to the scope of use or functionality. The computing device 500 may be part of a laser-enhanced direct print additive manufacturing platform that seamlessly integrates a photonic curing system along with direct write ink printing (micro-dispensing or aerosol jetting), thermal extrusion also known as fused deposition modeling (FDM), integrated micro-milling, and pick-and-place insertion.

Numerous other general purpose or special purpose computing devices environments or configurations may be used. Example additive manufacturing platforms include a uniquely configured nScrypt 450HD additive manufacturing platform which includes fully integrated and automated photonic curing, pico-second laser machining, micro-dispending (or aerosol jetting), thermal extrusion, micro-milling, and pick-and-place insertion of electronics. Examples of well-known computing devices, environments, and/or configurations that may be suitable for use include, but are not limited to, personal computers, server computers, handheld or laptop devices, multiprocessor systems, microprocessor-based systems, network personal computers (PCs), minicomputers, mainframe computers, embedded systems, distributed computing environments that include any of the above systems or devices, and the like.

Computer-executable instructions, such as program modules, being executed by a computer may be used. Generally, program modules include routines, programs, objects, components, data structures, etc. that perform particular tasks or implement particular abstract data types. Distributed computing environments may be used where tasks are performed by remote processing devices that are linked through a communications network or other data transmission medium. In a distributed computing environment, program modules and other data may be located in both local and remote computer storage media including memory storage devices.

With reference to FIG. 5, an exemplary system for implementing aspects described herein includes a computing device, such as computing device 500. In its most basic configuration, computing device 500 typically includes at least one processing unit 502 and memory 504. Depending on the exact configuration and type of computing device, memory 504 may be volatile (such as random-access memory (RAM)), non-volatile (such as read-only memory (ROM), flash memory, etc.), or some combination of the two. This most basic configuration is illustrated in FIG. 5 by dashed line 506.

Computing device 500 may have additional features/functionality. For example, computing device 500 may include additional storage (removable and/or non-removable) including, but not limited to, magnetic or optical disks or tape. Such additional storage is illustrated in FIG. 5 by removable storage 508 and non-removable storage 510.

Computing device 500 typically includes a variety of computer readable media. Computer readable media can be any available media that can be accessed by the device 500 and includes both volatile and non-volatile media, removable and non-removable media.

Computer storage media include volatile and non-volatile, and removable and non-removable media implemented in any method or technology for storage of information such as computer readable instructions, data structures, program modules or other data. Memory 504, removable storage 508, and non-removable storage 510 are all examples of computer storage media. Computer storage media include, but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by computing device 500. Any such computer storage media may be part of computing device 500.

Computing device 500 may contain communication connection(s) 512 that allow the device to communicate with other devices. Computing device 500 may also have input device(s) 514 such as a keyboard, mouse, pen, voice input device, touch input device, etc. Output device(s) 516 such as a display, speakers, printer, etc. may also be included. All these devices are well known in the art and need not be discussed at length here.

It should be understood that the various techniques described herein may be implemented in connection with hardware components or software components or, where appropriate, with a combination of both. Illustrative types of hardware components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. The methods and apparatus of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computer, the machine becomes an apparatus for practicing the presently disclosed subject matter.

Although exemplary implementations may refer to utilizing aspects of the presently disclosed subject matter in the context of one or more stand-alone computer systems, the subject matter is not so limited, but rather may be implemented in connection with any computing environment, such as a network or distributed computing environment. Still further, aspects of the presently disclosed subject matter may be implemented in or across a plurality of processing chips or devices, and storage may similarly be effected across a plurality of devices. Such devices might include personal computers, network servers, and handheld devices, for example.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A method for chip embedding comprising:
placing an integrated circuit chip into a dielectric substrate, wherein the integrated circuit chip comprises a plurality of pads;
connecting each of the plurality of pads to the dielectric substrate using conductive epoxy to form interconnects from each pad of the plurality of pads on to the dielectric substrate; and
covering the interconnects and the dielectric substrate with a dielectric liquid to form a dielectric layer on top of the dielectric substrate and the interconnects.

2. The method of claim 1, wherein the dielectric liquid comprises a dielectric ink.

3. The method of claim 2, wherein the dielectric ink hardens to form the dielectric layer.

4. The method of claim 1, wherein the conductive epoxy is adhesive and thixotropic.

5. The method of claim 1, wherein the conductive epoxy comprises EPO-TEK EK1000.

6. The method of claim 1, further comprising curing the conductive epoxy prior to covering the interconnects.

7. The method of claim 1, further comprising:
covering a top of the integrated circuit chip with the conductive epoxy.

8. The method of claim 7, further comprising covering the interconnects with the dielectric liquid without covering the conductive epoxy on top of the integrated circuit chip.

9. The method of claim 1, further comprising creating a via opening to the integrated circuit chip which can be refilled using the conductive epoxy to form a vertical interconnect.

10. The method of claim 1, wherein the integrated circuit chip comprises a QFN chip, a chip under any packaging form, or an unpackaged chip in its intrinsic die format.

11. The method of claim 1, further comprising milling a cavity into the dielectric substrate and placing the integrated circuit chip into the cavity.

12. The method of claim 11, wherein there is a gap formed between the integrated circuit chip and the cavity when the integrated circuit chip is placed in the cavity and further comprising filling the gap (both underneath and surrounding the integrated circuit chip) with the dielectric liquid.

13. The method of claim 12, wherein the interconnects extend over the gap.

14. The method of claim 1, wherein the connecting and covering steps are performed as part of a direct print additive manufacturing process.

15. A computer-readable medium with computer-executable instructions stored thereon that when executed by a computing device cause the computing device to:
place an integrated circuit chip into a dielectric substrate, wherein the integrated circuit chip comprises a plurality of pads;
connect each of the plurality of pads to the dielectric substrate using conductive epoxy to form interconnects from each pad of the plurality of pads on to the dielectric substrate; and
cover the interconnects and the dielectric substrate with a dielectric liquid to form a dielectric layer on top of the dielectric substrate and the interconnects.

16. The computer-readable medium of claim 15, further comprising milling a cavity into the dielectric substrate and placing the integrated circuit chip into the cavity.

17. The computer-readable medium of claim 16, wherein there is a gap formed between the integrated circuit chip and the cavity when the integrated circuit chip is placed in the cavity and further comprising filling the gap with the dielectric liquid.

18. The computer-readable medium of claim 17, wherein the interconnects extend over the gap.

19. The computer-readable medium of claim 15, wherein the computing device is part of an advanced additive manufacturing platform or a robotic and automated manufacturing system (or an advanced additive manufacturing platform in the form of a fully automated manufacturing tool, which is also known as a direct print additive manufacturing system).

20. A device comprising:
a dielectric substrate comprising a cavity;
an integrated circuit chip placed into the cavity and comprising a plurality of pads, wherein each of the plurality of pads is connected to the dielectric substrate using conductive epoxy to form interconnects from each of the plurality of pads on the dielectric substrate; and
a layer of dielectric liquid covering the interconnects and the dielectric substrate and filling a gap between the integrated circuit chip and the dielectric substrate, and wherein the dielectric liquid forms a dielectric layer on top of the dielectric substrate and the interconnects.
